(19) United States
(12) Patent Application Publication
(10) Pub. No.: US 2026/0155589 A1
(43) Pub. Date: Jun. 4, 2026

(54) PROBE AND DEVICE FOR CHARGING AND DISCHARGING SECONDARY BATTERY

(71) Applicant: Samsung SDI Co., Ltd., Yongin-si (KR)

(72) Inventor: Seokho Yun, Yongin-si (KR)

(73) Assignee: Samsung SDI Co., Ltd., Yongin-si (KR)

(21) Appl. No.: 19/367,096

(22) Filed: Oct. 23, 2025

(30) Foreign Application Priority Data
Dec. 3, 2024 (KR) 10-2024-0177949

(51) Int. Cl. H01R 4/48; G01R 31/3835; H01R 4/26

(52) U.S. Cl. CPC H01R 4/4872; G01R 31/3835; H01R 4/26

(57) ABSTRACT

The present disclosure relates to a secondary battery charging/discharging probe. The secondary battery charging/discharging probe includes a current pin including a first through hole in a length direction and configured to apply a current to a secondary battery through a current pin head disposed at one end portion, and a voltage pin inserted into the first through hole, and configured to sense a voltage of the secondary battery through a voltage pin head disposed at one end portion, wherein the voltage pin head includes a plurality of protrusions protruding to contact the secondary battery, and wherein the plurality of protrusions are disposed at a periphery of the voltage pin head.

### CROSS-REFERENCE TO RELATED APPLICATIONS

This present application claims priority to and the benefit under 35 U.S.C. § 119(a)-(d) of Korean Patent Application No. 10-2024-0177949, filed on Dec. 3, 2024, in the Korean Intellectual Property Office, the entire disclosure of which is incorporated herein by reference.

### FIELD

The present disclosure relates to a probe for charging and discharging a secondary battery and a device for charging and discharging a secondary battery.

### BACKGROUND

Unlike primary batteries that are not designed to be (re)charged, secondary (or rechargeable) batteries are batteries that are designed to be discharged and recharged. Low-capacity secondary batteries are used in portable, small electronic devices, such as smart phones, feature phones, notebook computers, digital cameras, and camcorders, while large-capacity secondary batteries are widely used as power sources for driving motors in hybrid vehicles and electric vehicles and for storing power (e.g., home and/or utility scale power storage). A secondary battery generally includes an electrode assembly composed of a positive electrode and a negative electrode, a case accommodating the same, and electrode terminals connected to the electrode assembly.

The charging and discharging process of a secondary battery may be repeatedly performed to test the activation process of the secondary battery or the performance or capacity of the completed secondary battery. Through this process, the state of the secondary battery may be monitored through pins that apply a current to the secondary battery and pins that sense a voltage of the secondary battery. The contact state between each pin and the secondary battery may significantly affect the charging-discharging efficiency or the monitoring quality. Therefore, there is a demand for improving the contact state between each pin and the secondary battery.

The herein information disclosed in this Background section is for enhancement of understanding of the background of the present disclosure, and therefore, it may contain information that does not constitute related (or prior) art.

### SUMMARY

The present disclosure aims to provide a probe for charging and discharging a secondary battery and a device for charging and discharging a secondary battery for solving the technical problems described herein.

These and other aspects and features of the present disclosure will be described in or will be apparent from the following description of embodiments of the present disclosure.

According to embodiments of the present disclosure, there is provided a secondary battery charging/discharging probe, including a current pin including a first through hole in a length direction and configured to apply a current to a secondary battery through a current pin head disposed at one end portion, and a voltage pin inserted into the first through hole, and configured to sense a voltage of the secondary battery through a voltage pin head disposed at one end portion, wherein the voltage pin head includes a plurality of protrusions protruding to contact the secondary battery, and wherein the plurality of protrusions are disposed at a periphery of the voltage pin head.

According to embodiments of the present disclosure, a number of the plurality of protrusions may range from four to twelve.

According to embodiments of the present disclosure, the plurality of protrusions may be circumferentially disposed at approximately equal distances around the voltage pin head.

According to embodiments of the present disclosure, a diameter of the voltage pin head may be in a range of 2 mm to 5.5 mm.

According to embodiments of the present disclosure, at least a part of the voltage pin head may be configured to protrude toward the secondary battery relative to one end portion of the current pin head.

According to embodiments of the present disclosure, in response to the secondary battery charging and discharging probe moving downwardly toward the secondary battery, the voltage pin head may contact the secondary battery first, and after the voltage pin head contacts the secondary battery, the voltage pin head may move rearwardly in a length direction of the voltage pin, and the current pin head may contact the secondary battery.

According to embodiments of the present disclosure, in response to the current pin head contacting the secondary battery, with the secondary battery charging/discharging probe moving upwardly, the voltage pin head may move forwardly toward a length direction of the voltage pin, wherein at least a part of the voltage pin head returns to a position that protrudes toward the secondary battery relative to one end portion of the current pin head.

According to embodiments of the present disclosure, at least a part of the voltage pin head may be configured to protrude toward the secondary battery relative to one end portion of the current pin head by 1 mm to 2 mm.

According to embodiments of the present disclosure, the secondary battery charging/discharging probe may further include a body including a second through hole in a length direction and configured to surround at least a part of an outer surface of the current pin, and a support member with one end portion supporting one end portion of the current pin head, and the other end portion supported by the body, wherein the current pin is inserted into the second through hole.

According to embodiments of the present disclosure, the support member may have an elasticity along a length direction of the body.

According to embodiments of the present disclosure, the support member may be configured to surround at least a part of the outer surface of the current pin.

According to embodiments of the present disclosure, the first through hole and the second through hole may be formed into a cylindrical shape, wherein a diameter of the first through hole is greater than a diameter of the voltage pin, and wherein a diameter of the second through hole is greater than a diameter of the current pin.

According to embodiments of the present disclosure, the secondary battery may be a cylindrical secondary battery.

According to embodiments of the present disclosure, the current pin head may include a plurality of protrusions protruding to contact the secondary battery.

According to embodiments of the present disclosure, there is provided a secondary battery charging/discharging device, including a first probe configured to contact an electrode terminal of a secondary battery; and a second probe configured to contact at least a part of the secondary battery having a different polarity from the electrode terminal, wherein at least one of the first probe and the second probe includes, a current pin including a first through hole in a length direction, and configured to apply a current to the secondary battery through a current pin head disposed at one end portion, and a voltage pin inserted into the first through hole, and configured to sense a voltage of the secondary battery through a voltage pin head disposed at one end portion, wherein the voltage pin head includes a plurality of protrusions protruding to contact an electrode terminal of the secondary battery, and wherein the plurality of protrusions are disposed at a periphery of the voltage pin head.

According to embodiments of the present disclosure, a number of the plurality of protrusions may range from four and twelve.

According to embodiments of the present disclosure, the plurality of protrusions may be circumferentially disposed at approximately equal distances around the voltage pin head.

According to embodiments of the present disclosure, a diameter of the voltage pin head may be between 2 mm and 5.5 mm.

According to embodiments of the present disclosure, at least a part of the voltage pin head may be configured to protrude toward the secondary battery relative to one end portion of the current pin head.

According to embodiments of the present disclosure, at least a part of the voltage pin head may be configured to protrude toward the secondary battery by 1 mm to 2 mm relative to one end portion of the current pin head.

According to various embodiments of the present disclosure, the pressure applied to the secondary battery during the charging and discharging process may be efficiently distributed.

According to various embodiments of the present disclosure, the structural deformation of the secondary battery that may occur during the charging and discharging process of the secondary battery may be minimized.

According to various embodiments of the present disclosure, the contact efficiency between a voltage pin head and a secondary battery may be improved, thereby enhancing the charging and discharging efficiency.

However, aspects and features of the present disclosure are not limited to those described herein, and other aspects and features not mentioned will be clearly understood by a person skilled in the art from the detailed description, described herein.

### BRIEF DESCRIPTION OF THE DRAWINGS

The following drawings attached to this specification illustrate embodiments of the present disclosure, and further describe aspects and features of the present disclosure together with the detailed description of the present disclosure. Thus, the present disclosure should not be construed as being limited to the drawings.

FIG. 1 is a view illustrated to explain a secondary battery and a probe for charging and discharging a secondary battery according to embodiments of the present disclosure;

FIG. 2 is a view illustrating a probe for charging and discharging a secondary battery according to embodiments of the present disclosure;

FIG. 3 is an exploded view illustrating detailed components of a probe for charging and discharging a secondary battery according to embodiments of the present disclosure;

FIG. 4 is a view illustrating a cylindrical secondary battery according to embodiments of the present disclosure;

FIG. 5 is a cross-sectional view illustrating a cylindrical secondary battery according to embodiments of the present disclosure;

FIG. 6A is a view illustrated to explain a probe for charging and discharging a secondary battery according to a comparative example;

FIG. 6B is a view illustrated to explain a probe for charging and discharging a secondary battery according to a comparative example;

FIG. 7A is a view illustrated to explain a probe for charging and discharging a secondary battery according to embodiments of the present disclosure;

FIG. 7B is a view illustrated to explain a probe for charging and discharging a secondary battery according to embodiments of the present disclosure;

FIG. 8 is a view illustrating an example of a downward movement of a probe for charging and discharging a secondary battery according to embodiments of the present disclosure;

FIG. 9 is a view illustrating an example of an upward movement of a probe for charging and discharging a secondary battery according to embodiments of the present disclosure; and

FIG. 10 is a view illustrated to explain a device for charging and discharging a secondary battery according to embodiments of the present disclosure.

### DETAILED DESCRIPTION

Hereinafter, embodiments of the present disclosure will be described, in detail, with reference to the accompanying drawings. The terms or words used in the present specification and claims are not to be limitedly interpreted as general or dictionary meanings and should be interpreted as meanings and concepts that are consistent with the technical idea of the present disclosure on the basis of the principle that an inventor can be his/her own lexicographer to appropriately define concepts of terms to describe his/her disclosure in the best way. Therefore, the embodiments described in this specification and the configurations shown in the drawings are only some of the embodiments of the present disclosure and do not represent all of the technical spirit, aspects, and features of the present disclosure. Accordingly, it should be understood that there may be various equivalents and modifications that can replace or modify the embodiments described herein at the time of filing this application.

Also, it will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

Also, in the figures, dimensions of the various elements, layers, etc. may be exaggerated for clarity of illustration. The same reference numerals designate the same elements.

References to two compared elements, features, etc. as being “the same” may mean that they are “substantially the same”. Thus, the phrase “substantially the same” may include a case having a deviation that is considered low in the art, for example, a deviation of 5% or less. In addition, when a certain parameter is referred to as being uniform in a given region, it may mean that it is uniform in terms of an average.

It will be understood that, although the terms first, second, etc. may be used herein to describe various elements, these elements should not be limited by these terms. These terms are only used to distinguish one element from another element. Thus, a first element could be termed a second element unless the context clearly indicates otherwise.

Throughout the specification, unless otherwise stated, each element may be singular or plural.

Arranging an arbitrary element “above (or below)” or “on (under)” another element may mean that the arbitrary element may be disposed in contact with the upper (or lower) surface of the element, and another element may also be interposed between the element and the arbitrary element disposed on (or under) the element.

In addition, it will be understood that when a component is referred to as being “linked,” “coupled,” or “connected” to another component, the elements may be directly “coupled,” “linked” or “connected” to each other, or another component may be “'interposed′ between the components”. It will also be understood that when an element is referred to as being “electrically coupled” to another element, it may be directly coupled to the other element or intervening elements may be present.

Throughout the specification, when “A and/or B” is stated, it means A, B or A and B, unless otherwise stated. That is, “and/or” includes any or all combinations of a plurality of items enumerated. When “C to D” is stated, it means C or more and D or less, unless otherwise specified.

The terminology used herein is for the purpose of describing embodiments of the present disclosure and is not intended to be limiting of the present disclosure.

In this specification, singular expressions include plural expressions unless the context clearly specifies singular expressions. In addition, plural expressions include singular expressions unless the context clearly specifies plural expressions. Throughout the specification, when a part is described as including a component, it implies that additional components may also be included unless specifically stated to the contrary.

According to embodiments of the present disclosure, the sizes and the relative sizes of layers and areas illustrated in the drawings may be exaggerated for clarity of explanation. The sizes in the drawings are only for ease of explanation, but the present disclosure is not limited thereto. Like reference numerals in the drawings denote like elements throughout the specification.

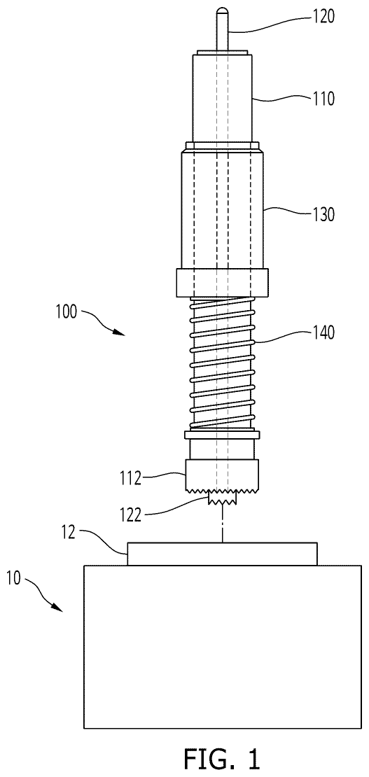

FIG. 1 is a view illustrating a secondary battery 10 and a secondary battery charging/discharging probe 100 according to embodiments of the present disclosure. Referring to FIG. 1, the secondary battery 10 may contact the secondary battery charging/discharging probe 100. Through this, the secondary battery charging/discharging probe 100 may apply a current to the secondary battery 10 or sense the voltage of the secondary battery 10.

The secondary battery 10 may be capable of charging and discharging. The secondary battery 10 may include a secondary battery case, an electrode assembly accommodated in the secondary battery case, and an electrolyte. For example, in the secondary battery, the electrode assembly with a separator disposed between a positive electrode and a negative electrode may be stacked or wound and sealed together with an electrolyte in the secondary battery case. The electrode assembly and the electrolyte accommodated in the secondary battery case may electrochemically react to generate energy.

The secondary battery 10 may include an electrode terminal 12 disposed on the top of the secondary battery 10. The electrode terminal 12 may also be disposed under the secondary battery 10. The electrode terminal 12 may function as a path for the electrical connection between the secondary battery 10 and external components. According to embodiments, the electrode terminal 12 may be a positive electrode terminal, but it is not limited thereto. According to embodiments, the secondary battery 10 may be a cylindrical secondary battery.

The secondary battery charging/discharging probe 100 may be in contact with the electrode terminal 12 of the secondary battery 10 and may apply a current to the secondary battery 10 or sense the voltage of the secondary battery 10. The secondary battery charging/discharging probe 100 may apply a current to the secondary battery 10 or sense the voltage of the secondary battery 10 on the upper side of the secondary battery 10 where the electrode terminal 12 is disposed. When the electrode terminal 12 is disposed under the secondary battery 10, the secondary battery charging/discharging probe 100 may apply a current to the secondary battery 10, or sense the voltage of the secondary battery 10 under the secondary battery 10 where the electrode terminal 12 is disposed.

The secondary battery charging/discharging probe 100 may include a current pin 110 for applying a current to the secondary battery 10 and a voltage pin 120 for sensing the voltage of the secondary battery 10. A current pin head 112 may be disposed at one end of the current pin 110. Through the current pin head 112, the current pin 110 may apply a current to the secondary battery 10. Additionally, a voltage pin head 122 may be disposed at one end of the voltage pin 120. The voltage pin 120 may sense the voltage of the secondary battery 10 through the voltage pin head 122. According to embodiments, at least a part of the voltage pin head 122 may protrude toward the secondary battery 10 further than one end portion of the current pin head 112. According to embodiments, at least a part of the voltage pin head 122 may protrude toward the secondary battery 10 by 1 mm to 2 mm further than one end portion of the current pin head 112, but the present disclosure is not limited thereto. Therefore, as shown in FIG. 1, the secondary battery charging/discharging probe 100 may have a shape in which the voltage pin head 122 protrudes toward the secondary battery 10 further than the current pin head 112.

The secondary battery charging/discharging probe 100 may further include a body 130 that surrounds at least a part of the outer surface of the current pin 110 and a support member 140 that is fixed by the body 130, and configured to surround at least a part of the outer surface of the current pin 110. According to embodiments, the support member 140 may have elasticity along the length direction of the body 130.

Each of the current pin head 112 and the voltage pin head 122 may include a plurality of protrusions formed by protruding from each of the current pin head 112 and the voltage pin head 122. The protrusions of each of the current pin head 112 and the voltage pin head 122 may contact the secondary battery 10. The contact quality with the secondary battery 10 may vary depending on the shape, the arrangement, and the number of the plurality of protrusions formed on the current pin head 112 or the voltage pin head 122. According to various embodiments of the present disclosure, the contact quality of the secondary battery charging/discharging probe 100 may be improved, thereby enhancing the charging/discharging efficiency of the secondary battery 10.

During the repeated charging and discharging process, the current pin head 112 or the voltage pin head 122 may repeatedly contact the electrode terminal 12 of the secondary battery 10. Pressing pressure may be applied to the secondary battery 10 by the current pin head 112 or the voltage pin head 122. Due to the pressure applied to the secondary battery 10, the secondary battery 10 may be structurally deformed. According to various embodiments of the present disclosure, the pressure applied to the secondary battery 10 during the charging and discharging process may be efficiently distributed. As a result, the structural deformation of the secondary battery 10 that may occur during the charging and discharging process of the secondary battery 10 may be minimized.

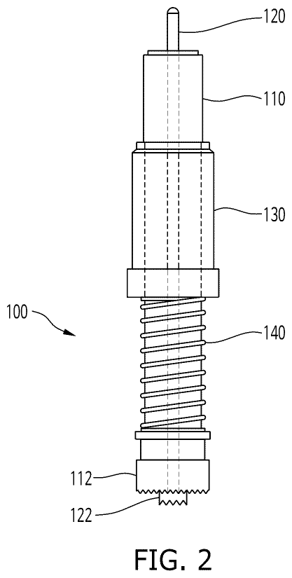

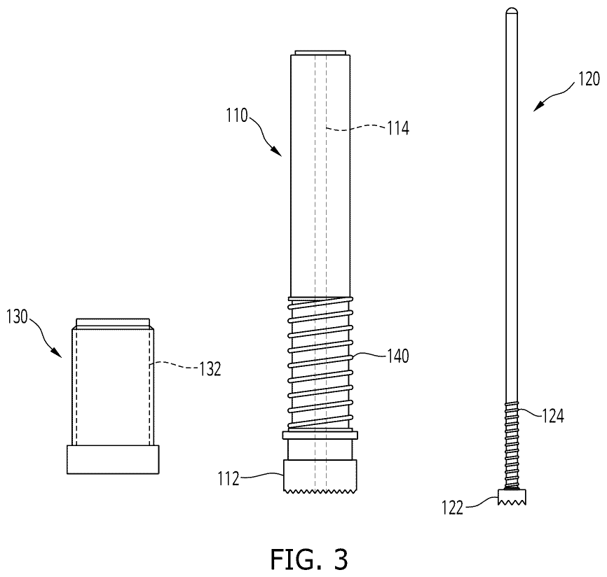

FIG. 2 is a view illustrating a secondary battery charging/discharging probe 100 according to embodiments of the present disclosure. FIG. 3 is an exploded view illustrating detailed components of the secondary battery charging/discharging probe 100 according to embodiments of the present disclosure.

Referring to FIGS. 2 and 3, the secondary battery charging/discharging probe 100 may include a current pin 110, a voltage pin 120, and a body 130. Additionally, the secondary battery charging/discharging probe 100 may further include a support member 140. The current pin 110, the voltage pin 120, the body 130, and the support member 140 may be combined to form the secondary battery charging/discharging probe 100. The secondary battery charging/discharging probe 100 may further include additional components.

The current pin 110 may have a first through hole 114 formed in the length direction. The first through hole 114 may be formed into a cylindrical shape. The diameter of the first through hole 114 may be greater than the diameter of the voltage pin 120. For example, the size of the first through hole 114 may be formed to be large enough to accommodate the voltage pin 120 combined with an elastic member 124 that surrounds at least a part of the outer surface of the voltage pin 120. Therefore, the voltage pin 120 may pass through the first through hole 114 and be coupled to the current pin 110.

The current pin 110 may include the current pin head 112 disposed at one end of the current pin 110. The current pin 110 may apply a current to a secondary battery (e.g., 10 in FIG. 1) through the current pin head 112. Specifically, a plurality of protrusions may be formed on the bottom of the current pin head 112 so that the current pin head 112 may contact the secondary battery, and when the current pin head 112 is in contact with the secondary battery, the current pin 110 may apply a current to the secondary battery.

The voltage pin 120 may be coupled to the current pin 110. For example, the voltage pin 120 may be inserted into the first through hole 114 of the current pin 110 and coupled to the current pin 110.

The voltage pin 120 may include the voltage pin head 122 disposed at one end portion of the voltage pin 120. The voltage pin 120 may sense the voltage of the secondary battery through the voltage pin head 122. Specifically, a plurality of protrusions may be formed on the bottom of the voltage pin head 122 so that the voltage pin head 122 contacts the secondary battery, and when the voltage pin head 122 contacts the secondary battery, the voltage pin 120 may sense the voltage of the secondary battery.

The secondary battery charging/discharging probe 100 may include a support member 140 that surrounds at least a part of the outer surface of the current pin 110. One end portion of the support member 140 may be supported by a protruding area formed on the inner surface of the second through hole 132 of the body 130. The protruding area formed on the inner surface of the second through hole 132 may be an area formed by at least a part of the second through hole 132 protruding toward the central direction of the body 130. The other end portion of the support member 140 may support the current pin head 112. Even though the current pin head 112 moves forwardly or rearwardly due to the elastic force of the support member 140, the current pin head 112 may return to its original state.

Additionally, the voltage pin 120 may further include the elastic member 124 that surrounds at least a part of the outer surface of the voltage pin 120. One end portion of the elastic member 124 may be supported by a protruding area formed on the inner surface of the first through hole 114. The protruding area formed on the inner surface of the first through hole 114 may be an area formed by at least a part of the first through hole 114 protruding toward the central direction of the current pin 110. The other end portion of the elastic member 124 may support the voltage pin head 122. Even though the voltage pin head 122 moves forwardly or rearwardly due to the elastic force of the elastic member 124, the voltage pin head 122 may return to its original state.

The body 130 may have a second through hole 132 formed in the length direction. The second through hole 132 may be formed into a cylindrical shape. Additionally, the diameter of the second through hole 132 may be greater than the diameter of the current pin 110. For example, the size of the second through hole 132 may be formed to be large enough to accommodate the current pin 110 combined with the support member 140 that surrounds at least a part of the outer surface of the current pin 110. Therefore, the current pin 110 may pass through the second through hole 132 to be coupled to the body 130.

According to embodiments, the voltage pin head 122 may include a plurality of protrusions formed to protrude to contact the secondary battery. The plurality of protrusions may be formed on the bottom of the voltage pin head 122 that faces the secondary battery. The plurality of protrusions may be disposed around the circumference of the voltage pin head 122. Each of the plurality of protrusions may refer to the most protruding portion among the portions protruding from the voltage pin head 122. Each of the most protruding portions among the portions protruding from the voltage pin head 122 may be disposed along the periphery of the bottom of the voltage pin head 122. As a result, when the voltage pin head 122 contacts the secondary battery, the pressure applied to the secondary battery may be efficiently distributed. As the pressure applied to the secondary battery is efficiently distributed, the structural deformation of the secondary battery that may occur during the charging and discharging process may be minimized.

According to embodiments, the plurality of protrusions may be disposed at equal distances along the periphery of the bottom of the voltage pin head 122. As a result, when the voltage pin head 122 contacts the secondary battery, the pressure applied to the secondary battery may be uniformly distributed through each of the plurality of protrusions.

According to embodiments, the number of plurality of protrusions may be four to twelve, but the present disclosure is not limited thereto. According to embodiments, the diameter of the voltage pin head 122 may be 2 mm to 5.5 mm, but the present disclosure is not limited thereto.

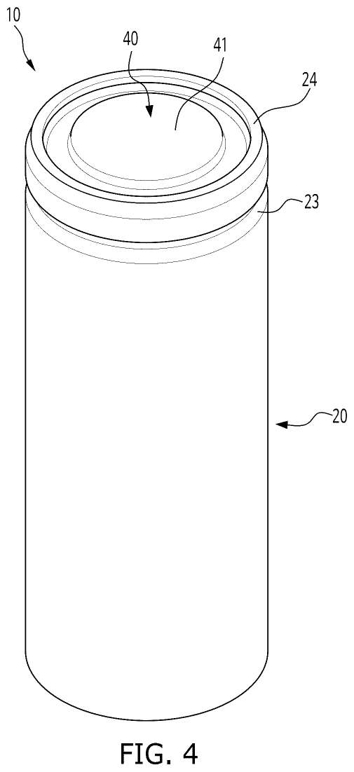

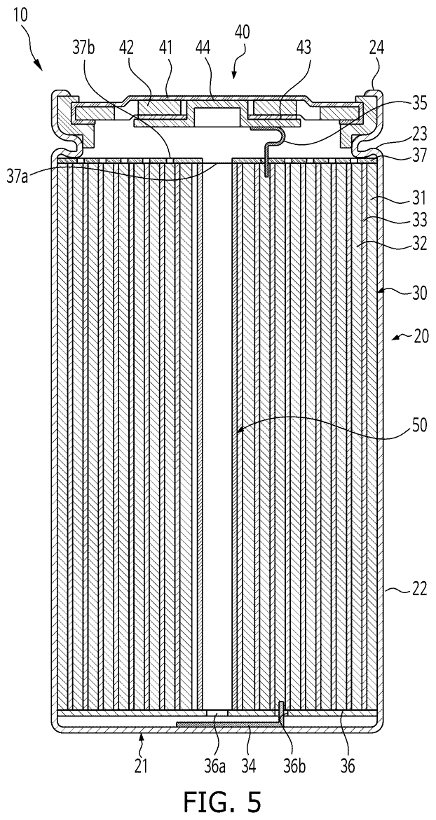

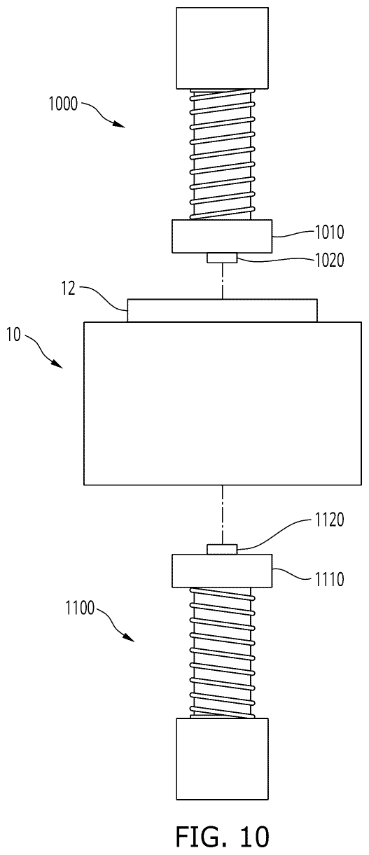

FIG. 4 is a view illustrating a cylindrical secondary battery according to embodiments of the present disclosure. FIG. 5 is a cross-sectional view illustrating a cylindrical secondary battery according to embodiments of the present disclosure. The secondary battery 10 of FIGS. 4 and 5 may correspond to the secondary battery 10 of FIG. 10.

As shown in FIGS. 3 and 4, a cylindrical lithium ion secondary battery 10 according to one or more embodiments of the present disclosure may include a cylindrical can 20, an electrode assembly 30, and a cap assembly 40. In addition, in some embodiments, the cylindrical lithium ion secondary battery 10 may include a center pin 50. In addition, in the secondary battery 10 according to one or more embodiments of the present disclosure, the cap assembly 40 may also perform a current interruption operation and, thus, may sometimes be referred to as a current interrupt device (CID).

The cylindrical can 20 may have a substantially circular bottom part 21 and a cylindrical sidewall 22 upwardly extending (e.g., extending a predetermined length) from a circumference (or a periphery) of the bottom part 21. During the manufacturing process of the secondary battery 10, the top portion of the cylindrical can 20 is open. Therefore, during the assembly process of the secondary battery 10, the electrode assembly 30 and the center pin 50 may be inserted into the cylindrical can 20 together with an electrolyte. The cylindrical can 20 may be made of, for example, steel, stainless steel, aluminum, aluminum alloy, or an equivalent thereof but is not limited to.

In addition, to prevent the cap assembly 40 from escaping to the outside (e.g., being separated from the cylindrical can 20), with respect to the cap assembly 40, the cylindrical can 20 may include a beading part (e.g., a bead) 23 recessed toward the inside at the bottom of the cap assembly 40 and a crimping part (e.g., a crimp) 24 bent inwardly at the top thereof.

The electrode assembly 30 may be accommodated inside the cylindrical can 20. The electrode assembly 30 may include a negative electrode plate 31 coated with a negative electrode active material (e.g., graphite, carbon, etc.) on a negative electrode current collector plate, a positive electrode plate 32 coated with a positive electrode active material (e.g., a transition metal oxide, such as LiCoO2, LiNiO2, LiMn2O4, etc.) on a positive electrode current collector plate, and a separator 33 positioned between the negative electrode plate 31 and the positive electrode plate 32 to prevent a short circuit therebetween while allowing the movement of lithium ions therethrough. In addition, the negative electrode plate 31, the positive electrode plate 32, and the separator 33 may be wound in a substantially cylindrical shape. In one embodiment, the negative electrode current collector may be made of copper (Cu) foil, the positive electrode current collector may be made of aluminum (Al) foil, and the separator may be made of polyethylene (PE) or polypropylene (PP), but the present disclosure is not limited thereto.

In addition, a negative electrode tab 34 protruding and extending a certain length (e.g., a suitable length) downwardly from the electrode assembly 30 may be welded to the negative electrode plate 31, and a positive electrode tab 35 protruding and extending a certain length (e.g., a suitable length) upwardly from the electrode assembly 30 may be welded to the positive electrode plate 32, but an opposite configuration is possible. In addition, for example, the negative electrode tab 34 may be made of copper (Cu) or nickel (Ni), and the positive electrode tab 35 may be made of aluminum (Al), but the present disclosure is not limited thereto.

In addition, the negative electrode tab 34 of the electrode assembly 30 may be welded to the bottom part 21 of the cylindrical can 20. Therefore, the cylindrical can 20 may act as a negative electrode. Of course, alternatively, the positive electrode tab 35 may be welded to the bottom part 21 of the cylindrical can 20, and in such embodiments, the cylindrical can 20 may act as a positive electrode.

In addition, the secondary battery 10 may include a first insulation plate 36 coupled to the cylindrical can 20, may have a first hole 36a in the center and one or more second holes 36b outside (e.g., peripheral to the center) thereof, and may be interposed between the electrode assembly 30 and the bottom part 21. The first insulation plate 36 prevents the electrode assembly 30 from electrically contacting the bottom part 21 of the cylindrical can 20. By way of example, the first insulation plate 36 prevents the positive electrode plate 32 of the electrode assembly 30 from electrically contacting the bottom part 21. The first hole 36a allows the gas to quickly move updwardly through the center pin 50 if (or when) a large amount of gas is generated due to an abnormality of the secondary battery 10, and one or more second holes 36b allow the negative electrode tab 34 to penetrate (or extend) therethrough and be welded to the bottom part 21.

In addition, the secondary battery 10 may include a second insulation plate 37 coupled to the cylindrical can 20, having a first hole 37a in the center and a plurality of second holes 37b formed outside thereof (e.g. located peripherally to the center), and may be interposed between the electrode assembly 30 and the cap assembly 40. The second insulation plate 37 prevents the electrode assembly 30 from electrically contacting the cap assembly 40. By way of example, the second insulation plate 37 prevents the negative electrode plate 31 of the electrode assembly 30 from electrically contacting the cap assembly 40. The first hole 37a allows the gas to quickly move toward the cap assembly 40 if (or when) a large amount of gas is generated due to an abnormality of the secondary battery, and the second holes 37b allow the positive electrode tab 35 to penetrate (or extend) therethrough and be welded to the cap assembly 40. In addition, the remaining second holes 37b allow an electrolyte to quickly flow into the electrode assembly 30 in an electrolyte injection process.

In addition, the diameters of the first holes 36a and 37a of the first and second insulation plates 36 and 37 are formed to be smaller than the diameter of the center pin 50, thereby preventing the center pin 50 from electrically contacting the bottom part 21 of the cylindrical can 20 or the cap assembly 40 due to an external impact.

The center pin 50 has a shape of a hollow circular pipe and may be coupled to the center of the electrode assembly 30. The center pin 50 may be made of, for example, steel, stainless steel, aluminum, an aluminum alloy, or polybutylene terephthalate, but the present disclosure is not limited thereto. The center pin 50 suppresses (or prevents) deformation of the electrode assembly 30 during charging and discharging of the battery and acts as a passage for gas generated inside the secondary battery. Of course, in some embodiments, the center pin 50 may be omitted.

The cap assembly 40 may include a top plate 41, a middle plate 42, an insulation plate 43, and a bottom plate 44.

The middle plate 42 is located below the top plate 41 and may have a substantially flat shape.

When viewed from the bottom, the insulation plate 43 may be formed in a circular ring shape having a suitable width (e.g., a predetermined width). In addition, the insulation plate 43 insulates the middle plate 42 and the bottom plate 44 from each other. The insulation plate 43 may be interposed between, for example, the middle plate 42 and the bottom plate 44 to then be ultrasonically welded, but the present disclosure is not limited thereto.

In the present disclosure, the top of the secondary battery 10 may refer to the surface corresponding to the cap assembly 40 of the secondary battery 10. The top of the secondary battery 10 may indicate the upper side of the secondary battery 10 shown in FIGS. 4 and 5. However, the present disclosure is not limited thereto. According to some embodiments, the cap assembly 40 may function as an electrode terminal (e.g., 12 in FIG. 1).

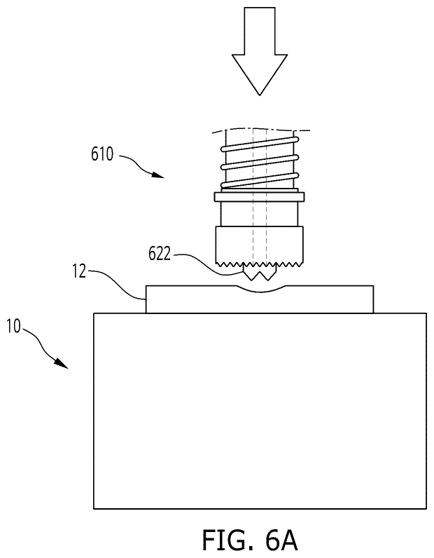

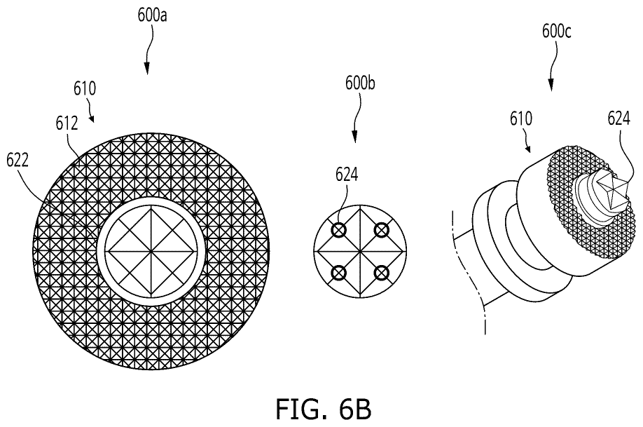

FIG. 6A is a view illustrating a secondary battery charging/discharging probe 610 according to a comparative example. FIG. 6B is a view illustrating a secondary battery charging/discharging probe 610 according to a comparative example.

FIG. 6A illustrates an example where the secondary battery charging/discharging probe 610 contacts the secondary battery 10 according to a comparative example. For the purpose of clarity, the portion of the secondary battery charging/discharging probe 610 that contacts the secondary battery 10 is enlarged and the remaining portions are omitted, and the sizes shown in the drawing are not limited thereto.

A voltage pin head 622 of the secondary battery charging/discharging probe 610 may contact the secondary battery 10. Specifically, the voltage pin head 622 of the secondary battery charging/discharging probe 610 may contact the top of the electrode terminal 12 of the secondary battery 10. The voltage pin head 622 may include a plurality of protrusions formed to protrude to contact the secondary battery 10. During the charging and discharging process, pressing pressure may be applied to the secondary battery 10 by the plurality of protrusions, and the secondary battery 10 may be structurally deformed.

FIG. 6B illustrates the secondary battery charging/discharging probe 610 according to a comparative example. FIG. 6B illustrates an exemplary configuration 600a of the secondary battery charging/discharging probe 610 viewed from below. The secondary battery charging/discharging probe 610 may include a current pin (not shown) including a current pin head 612 and a voltage pin (not shown) including a voltage pin head 622. Each of the current pin head 612 and the voltage pin head 622 may include a plurality of protrusions formed by protruding from each of the current pin head 612 and the voltage pin head 622.

FIG. 6B illustrates an exemplary configuration 600b of the voltage pin head 622 viewed from below. The voltage pin head 622 may include a plurality of protrusions 624. Each of the plurality of protrusions may refer to the most protruding portion of the portions protruding from the voltage pin head 622 (indicated by bold circles). As shown in the drawing, each of the plurality of protrusions 624 may be disposed on the inner area of the bottom of the voltage pin head 622, rather than on the periphery of the bottom of the voltage pin head 622. For example, each of the plurality of protrusions 624 may be disposed near the center of the voltage pin head 622.

An exemplary perspective view 600c of the secondary battery charging/discharging probe 610 is provided. As shown in the drawing, the secondary battery charging/discharging probe 610 may include a voltage pin head, and the voltage pin head may include the plurality of protrusions 624.

Referring to FIG. 6A, when the voltage pin head 622 contacts the secondary battery 10, each of the plurality of protrusions formed by protruding from the voltage pin head 622 may be disposed near the center of the voltage pin head 622. As a result, the pressing pressure by the plurality of protrusions, which is applied to the secondary battery 10 during the charging and discharging process, may be concentrated near the center of the voltage pin head 622. This may intensify the structural deformation of the secondary battery 10 and reduce charging and discharging efficiency.

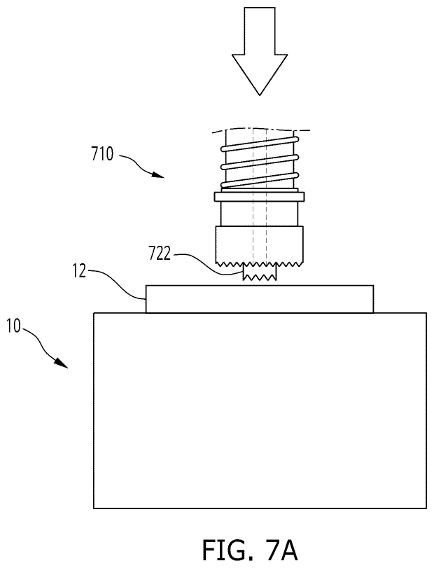

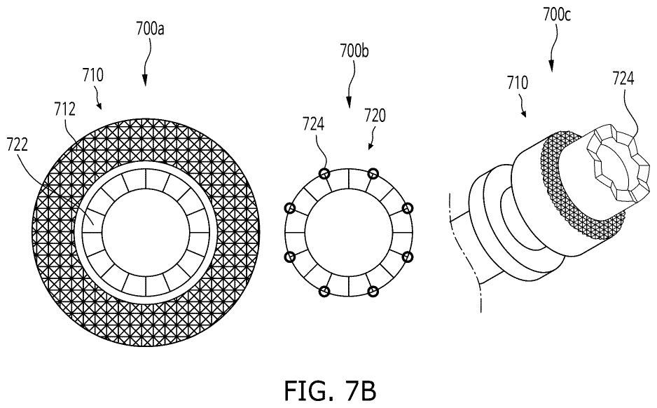

FIG. 7A is a view illustrating a secondary battery charging/discharging probe 710 according to embodiments of the present disclosure. FIG. 7B is a view illustrating a secondary battery charging/discharging probe 710 according to embodiments of the present disclosure.

FIG. 7A illustrates an example where the secondary battery charging/discharging probe 710 according to embodiments of the present disclosure is in contact with the secondary battery 10. For the purpose of clarity, the portion of the secondary battery charging/discharging probe 710 that contacts the secondary battery 10 is enlarged and the remaining portions are omitted, and the sizes shown in the drawing are not limited thereto.

A voltage pin head 722 of the secondary battery charging/discharging probe 710 may contact the secondary battery 10. Specifically, the voltage pin head 722 of the secondary battery charging/discharging probe 710 may contact the top of the electrode terminal 12 of the secondary battery 10. The voltage pin head 722 may include a plurality of protrusions formed to protrude to contact the secondary battery 10. During the charging and discharging process, pressing pressure may be applied to the secondary battery 10 by the plurality of protrusions, and the secondary battery 10 may be structurally deformed.

FIG. 7B illustrates the secondary battery charging/discharging probe 710 according to embodiments of the present disclosure. FIG. 7B illustrates an exemplary configuration 700a of the secondary battery charging/discharging probe 710 viewed from below. The secondary battery charging/discharging probe 710 may include a current pin (not shown) including a current pin head 712 and a voltage pin (not shown) including a voltage pin head 722. Each of the current pin head 712 and the voltage pin head 722 may include a plurality of protrusions formed by protruding from the respective bottoms of the current pin head 712 and the voltage pin head 722.

FIG. 7B illustrates an exemplary configuration 700b of the voltage pin head 722 viewed from below. The voltage pin head 722 may include a plurality of protrusions 724. Each of the plurality of protrusions 724 may refer to the most protruding portion among the portions protruding from the bottom of the voltage pin head 722 (indicated by thick circles). As shown in the drawing, each of the plurality of protrusions 724 may be disposed along the periphery of the bottom of the voltage pin head 722. For example, eight protrusions 724 may be disposed around the periphery of the bottom of the voltage pin head 722. According to embodiments, the plurality of protrusions may be circumferentially disposed at equal distances around the voltage pin head 722.

FIG. 7B illustrates an exemplary perspective view 700c of the secondary battery charging/discharging probe 710. As shown in the drawing, the secondary battery charging/discharging probe 710 may include a voltage pin head, and the voltage pin head may include the plurality of protrusions 724.

Referring to FIG. 7A, when the voltage pin head 722 contacts the secondary battery 10, each of the plurality of protrusions formed by protruding from the voltage pin head 722 may be disposed along the periphery of the bottom of the voltage pin head 722. As a result, the pressing pressure applied to the secondary battery 10 by the plurality of protrusions during the charging and discharging process may be distributed to the outer periphery of the voltage pin head 722. Therefore, the structural deformation of the secondary battery 10 may be minimized, and the contact efficiency between the voltage pin head 722 and the secondary battery 10 may increase, thereby enhancing the charging/discharging efficiency.

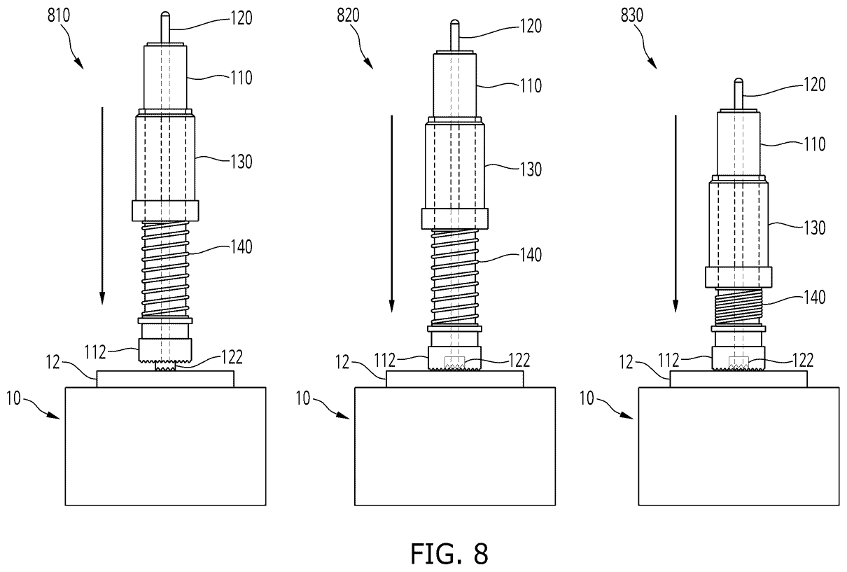

FIG. 8 is a view illustrating an example of the downward movement of the secondary battery charging/discharging probe 100 according to embodiments of the present disclosure. Referring to FIG. 8, the secondary battery charging/discharging probe 100 may include a current pin 110, a voltage pin 120, a body 130, and a support member 140, and the current pin 110 may include a current pin head 112, and the voltage pin 120 may include a voltage pin head 122. According to embodiments, the support member 140 may have an elastic force along the length direction of the body 130.

The secondary battery charging/discharging probe 100 may be lowered toward the secondary battery 10. The secondary battery charging/discharging probe 100 may be configured to be lowered toward the secondary battery 10 by external components. As shown in a first operation 810, at least a part of the voltage pin head 122 may be formed to protrude toward the secondary battery 10 further than one end of the current pin head 112. As a result, when the secondary battery charging/discharging probe 100 moves downwardly, the voltage pin head 122 may contact the secondary battery 10 prior to the current pin head 112.

The secondary battery charging/discharging probe 100 may further move downwardly toward the secondary battery 10. As shown in a second operation 820, the voltage pin head 122 may relatively move rearwardly or updwardly along the length direction of the first through hole (not shown) of the current pin 110 compared to the current pin 110, so that the current pin head 112 may contact the secondary battery 10. The movement rearwardly or updwardly of the voltage pin head 122 may refer to the movement rearwardly or updwardly of the voltage pin 120. Additionally, an elastic member (not shown) disposed to surround at least a part of the outer surface of the voltage pin 120 may contract.

The secondary battery charging/discharging probe 100 may further move toward the secondary battery 10. As shown in a third operation 830, the current pin 110 may move rearwardly and updwardly relative to the body 130 along the length direction of the second through hole (not shown) of the body 130. The movement rearwardly or updwardly of the current pin 110 may refer to the movement rearwardly or updwardly of the current pin head 112. The contact force between the current pin head 112 and the secondary battery 10 and the contact force between the voltage pin head 122 and the secondary battery 10 may be strengthened. Additionally, the pressing pressure applied to the secondary battery 10 may increase. The support member 140 disposed to surround at least a part of the outer surface of the current pin 110 may contract.

When the secondary battery charging/discharging probe 100 and the secondary battery 10 are in contact with each other, the charging/discharging of the secondary battery 10 may be performed.

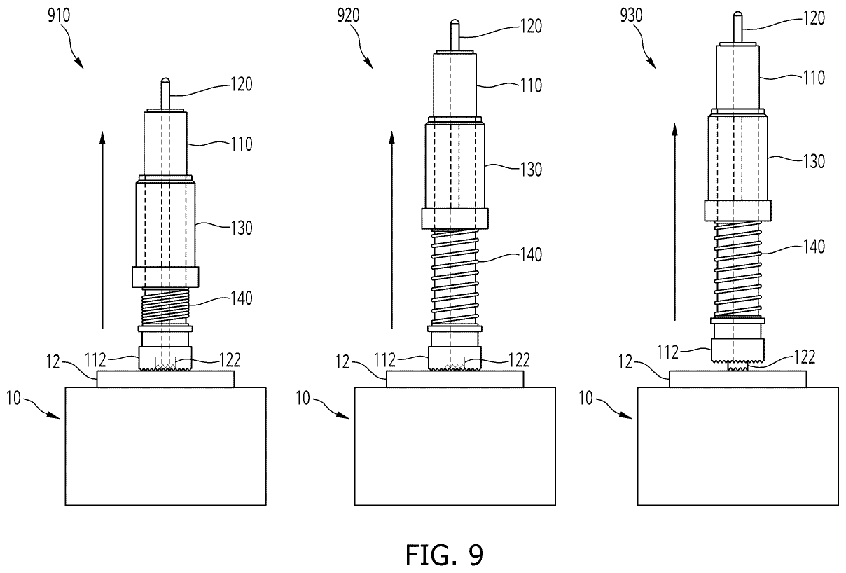

FIG. 9 is a view illustrating an example of the upward movement of the secondary battery charging/discharging probe 100 according to embodiments of the present disclosure. Referring to FIG. 9, the secondary battery charging/discharging probe 100 may include a current pin 110, a voltage pin 120, a body 130, and a support member 140, and the current pin 110 may include a current pin head 112, and the voltage pin 120 may include the voltage pin head 122.

As shown in a first operation 910, when the secondary battery charging/discharging probe 100 and the secondary battery 10 are in contact, the charging/discharging of the secondary battery 10 may be performed.

After the charging and discharging of the secondary battery 10 is performed, the secondary battery charging/discharging probe 100 may move updwardly from the secondary battery 10. The secondary battery charging/discharging probe 100 may be configured to move updwardly from the secondary battery 10 by external components. As shown in a second operation 920, the current pin 110 may move forwardly or downwardly relative to the body 130 along the length direction of the second through hole (not shown) of the body 130, and the support member 140 disposed to surround at least a part of the outer surface of the current pin 110 may expand.

The secondary battery charging/discharging probe 100 may further move updwardly from the secondary battery 10. As shown in a third operation 930, the voltage pin head 122 may move forwardly or downwardly relative to the current pin 110 along the length direction of the first through hole (not shown) of the current pin 110, and an elastic member (not shown) disposed to surround at least a part of the outer surface of the voltage pin 120 may expand. The voltage pin head 122 may return to its original position, which further protrudes than one end portion of the current pin head 112.

FIG. 10 is a view illustrating a secondary battery charging/discharging device according to embodiments of the present disclosure. Referring to FIG. 10, the secondary battery charging/discharging device may include a first probe 1000 and a second probe 1100. The first probe 1000 may contact the electrode terminal 12 of the secondary battery 10. The second probe 1100 may contact at least a part of the secondary battery 10 having a different polarity from the electrode terminal 12. For example, in the examples of FIGS. 4 and 5, when a cylindrical can 20 functions as a negative electrode or a positive electrode, the second probe 1100 may contact at least a part of the cylindrical can 20.

The first probe 1000 and the second probe 1100 may each correspond to the secondary battery charging/discharging probe 100 described in FIG. 1 to FIG. 9. Therefore, the description of the secondary battery charging/discharging probe 100 may be applied to each of the first probe 1000 and the second probe 1100. For example, the first probe 1000 may include a first current pin head 1010 and a first voltage pin head 1020, and the second probe 1100 may include a second current pin head 1110 and a second voltage pin head 1120. The redundant description will be omitted.

Embodiments of the present disclosure described herein have been disclosed for exemplification, and it is to be understood for those skilled in the art that various modifications, changes, and additions are possible within the spirit and scope of the present disclosure. It will be apparent that various modifications, changes, and additions may be made within the scope of the appended claims.

Various modifications, variations, and changes can be made by a person skilled in the art to which the present disclosure belongs within the scope of the technical spirit of the present disclosure and the claims, but the present disclosure is not limited to the embodiments described herein and the attached drawings.

Although the present disclosure has been described herein with respect to embodiments thereof, the present disclosure is not limited thereto. Various modifications and variations can be made thereto by those skilled in the art within the spirit of the present disclosure and the equivalent scope of the appended claims.

What is claimed is:

1. A secondary battery charging/discharging probe, comprising:
a current pin including a first through hole in a length direction and configured to apply a current to a secondary battery through a current pin head disposed at one end portion; and
a voltage pin inserted into the first through hole, and configured to sense a voltage of the secondary battery through a voltage pin head disposed at one end portion,
wherein:
the voltage pin head comprises a plurality of protrusions protruding to contact the secondary battery, and
the plurality of protrusions are disposed at a periphery of the voltage pin head.

2. The secondary battery charging/discharging probe as claimed in claim 1, wherein a number of the plurality of protrusions ranges from four to twelve.

3. The secondary battery charging/discharging probe as claimed in claim 1, wherein the plurality of protrusions are circumferentially disposed at approximately equal distances around the voltage pin head.

4. The secondary battery charging/discharging probe as claimed in claim 1, wherein a diameter of the voltage pin head is in a range of 2 mm to 5.5 mm.

5. The secondary battery charging/discharging probe as claimed in claim 1,
wherein at least a part of the voltage pin head is configured to protrude toward the secondary battery relative to one end portion of the current pin head.

6. The secondary battery charging/discharging probe as claimed in claim 5,
wherein, in response to the secondary battery charging and discharging probe moving downwardly toward the secondary battery, the voltage pin head contacts the secondary battery first, and after the voltage pin head contacts the secondary battery, the voltage pin head moves rearwardly in a length direction of the voltage pin, and the current pin head contacts the secondary battery.

7. The secondary battery charging/discharging probe as claimed in claim 6,
wherein, in response to the current pin head contacting the secondary battery, with the secondary battery charging/discharging probe moving upwardly,
the voltage pin head moves forwardly toward a length direction of the voltage pin, and
at least a part of the voltage pin head returns to a position that protrudes toward the secondary battery relative to one end portion of the current pin head.

8. The secondary battery charging/discharging probe as claimed in claim 1, wherein at least a part of the voltage pin head is configured to protrude toward the secondary battery relative to one end portion of the current pin head by 1 mm to 2 mm.

9. The secondary battery charging/discharging probe as claimed in claim 1, further comprising:
a body including a second through hole in a length direction and configured to surround at least a part of an outer surface of the current pin; and
a support member with one end portion supporting one end portion of the current pin head, and the other end portion supported by the body,
wherein the current pin is inserted into the second through hole.

10. The secondary battery charging/discharging probe as claimed in claim 9, wherein the support member has an elasticity along a length direction of the body.

11. The secondary battery charging/discharging probe as claimed in claim 9, wherein the support member is configured to surround at least a part of the outer surface of the current pin.

12. The secondary battery charging/discharging probe as claimed in claim 9, wherein the first through hole and the second through hole are formed into a cylindrical shape,
wherein a diameter of the first through hole is greater than a diameter of the voltage pin, and
wherein a diameter of the second through hole is greater than a diameter of the current pin.

13. The secondary battery charging/discharging probe as claimed in claim 1, wherein the secondary battery is a cylindrical secondary battery.

14. The secondary battery charging/discharging probe as claimed in claim 1, wherein the current pin head comprises a plurality of protrusions protruding to contact the secondary battery.

15. A secondary battery charging/discharging device, comprising:
a first probe configured to contact an electrode terminal of a secondary battery; and
a second probe configured to contact at least a part of the secondary battery having a different polarity from the electrode terminal,
wherein at least one of the first probe and the second probe comprises:
a current pin including a first through hole in a length direction, and configured to apply a current to the secondary battery through a current pin head disposed at one end portion, and
a voltage pin inserted into the first through hole, and configured to sense a voltage of the secondary battery through a voltage pin head disposed at one end portion,
wherein:
the voltage pin head comprises a plurality of protrusions protruding to contact an electrode terminal of the secondary battery, and
the plurality of protrusions are disposed at a periphery of the voltage pin head.

16. The secondary battery charging/discharging device as claimed in claim 15,
wherein a number of the plurality of protrusions ranges between four and twelve.

17. The secondary battery charging/discharging device as claimed in claim 15,
wherein the plurality of protrusions are circumferentially disposed at approximately equal distances around the voltage pin head.

18. The secondary battery charging/discharging device as claimed in claim 15,
wherein a diameter of the voltage pin head is between 2 mm and 5.5 mm.

19. The secondary battery charging/discharging device as claimed in claim 15,
wherein at least a part of the voltage pin head is configured to protrude toward the secondary battery relative to one end portion of the current pin head.

20. The secondary battery charging/discharging device as claimed in claim 15,
wherein at least a part of the voltage pin head is configured to protrude toward the secondary battery by 1 mm to 2 mm relative to one end portion of the current pin head.
